(19) United States
(12) Patent Application Publication
(10) Pub. No.: US 2023/0185182 A1
(43) Pub. Date: Jun. 15, 2023

(54) OPTICAL PROXIMITY CORRECTION METHOD AND SYSTEM, MASK, AND STORAGE MEDIUM

(71) Applicant: Semiconductor Manufacturing International (Beijing) Corporation, Beijing (CN)

(72) Inventors: Ge ZHANG, Shanghai (CN); Zhongwen YAN, Shanghai (CN)

(73) Assignee: Semiconductor Manufacturing International (Shanghai) Corporation, Shanghai (CN)

(21) Appl. No.: 17/986,104

(22) Filed: Nov. 14, 2022

(30) Foreign Application Priority Data
Dec. 15, 2021 (CN) 202111533657.0

(51) Int. Cl. G03F 1/38; G03F 1/70; G06F 30/398

(52) U.S. Cl. CPC G03F 1/38; G03F 1/70; G06F 30/398

(57) ABSTRACT

The present disclosure relates to an optical proximity correction method and system. The correction method may include providing main patterns and setting a forbidden edge rule according to a spacing between adjacent main patterns. The method may further include adding an auxiliary pattern to a side portion of the main patterns. A quantity of auxiliary patterns added to side portions of the main patterns is obtained based on the forbidden edge rule. The forbidden edge rule defines whether an edge of the main patterns is a forbidden edge, and an auxiliary pattern is not added to a side portion of the forbidden edge.

### CROSS REFERENCE TO RELATED APPLICATIONS

This application is based on and claims priority to Chinese patent Application No. 202111533657.0, filed Dec. 15, 2021, the entire content of which is incorporated herein by reference.

### TECHNICAL FIELD

The present disclosure relates to the field of semiconductor manufacturing, and in particular, to an optical proximity correction method and system, a mask, a device, and a storage medium.

### BACKGROUND

In the semiconductor manufacturing, with continuous reduction in the design size, the design size gets closer to the limit of a lithography imaging system, and the diffraction effect of light becomes more and more obvious, resulting in optical image degradation of design patterns. The actually formed lithography pattern is seriously distorted relative to the pattern on the mask, and the actual pattern formed by lithography on the silicon wafer is different from the design pattern. This phenomenon is referred to as an optical proximity effect (OPE).

Currently, the correction process for the OPE requires a great deal of time and effort.

### SUMMARY

The forms of the present disclosure provide an optical proximity correction method and system, a mask, a device, and a storage medium, to improve a result of optical proximity correction processing.

In an aspect of the present disclosure, an optical proximity correction method is provided. The method may include: providing main patterns; setting a forbidden edge rule according to a spacing between adjacent main patterns; and adding an auxiliary pattern to a side portion of the main patterns. A quantity of auxiliary patterns added to side portions of the main patterns is obtained based on the forbidden edge rule. The forbidden edge rule defines whether an edge of the main patterns is a forbidden edge, and an auxiliary pattern is not added to a side portion of the forbidden edge.

In another aspect of the present disclosure, an optical proximity correction system is provided. The optical proximity correction system may include a memory operable to store computer-readable instructions and a processor circuitry operable to read the computer-readable instructions stored in the memory. When executing the computer-readable instructions, the processor circuitry may be configured to: provide main patterns; set a forbidden edge rule according to a spacing between adjacent main patterns; and add an auxiliary pattern to a side portion of the main patterns. A quantity of the auxiliary patterns added to side portions of the main patterns is obtained based on the forbidden edge rule. The forbidden edge rule defines whether an edge of the main patterns is a forbidden edge, and an auxiliary pattern is not added to a side portion of the forbidden edge.

In another aspect of the present disclosure, a mask is provided which may include patterns obtained using the optical proximity correction method provided in the forms of the present disclosure.

In another aspect of the present disclosure, a non-transitory machine-readable media is provided which has instructions stored on the machine readable media. When being executed, the instructions may case a machine to: provide main patterns; set a forbidden edge rule according to a spacing between adjacent main patterns; and add an auxiliary pattern to a side portion of the main patterns. A quantity of the auxiliary patterns added to side portions of the main patterns is obtained based on the forbidden edge rule. The forbidden edge rule defines whether an edge of the main patterns is a forbidden edge, and an auxiliary pattern is not added to a side portion of the forbidden edge.

Compared with the prior art, the forms of the present disclosure have the following advantages.

In the optical proximity correction method provided in the forms of the present disclosure, the forbidden edge rule is set according to the spacing between adjacent main patterns, and the auxiliary pattern is added to each side portion of the main patterns. The quantity of the auxiliary patterns added to the side portions of the main patterns is obtained based on the forbidden edge rule. The auxiliary patterns are usually sub-resolution assist features. That is, the auxiliary pattern is an unexposable pattern. By adding the auxiliary patterns around the main pattern, the imaging deviation generated by different main patterns due to different diffraction effects is reduced. Therefore, the fidelity of patterns can be improved, and the lithography quality of the main patterns can be enhanced. In addition, in this form, the forbidden edge rule is set, and the quantity of the auxiliary patterns added to the side portions of the main patterns is obtained based on the forbidden edge rule, so that the auxiliary patterns can be added according to the actual environmental condition around the main pattern. In this way, a result of the optical proximity correction processing is improved.

In some forms, in the layout layer, the main auxiliary patterns are sequentially added to side portions of the feasible edges of the main pattern in ascending order of the quantity of the feasible edges of the each main pattern. The ascending order of the quantity of the feasible edges of the main pattern is descending order of a quantity of the forbidden edges of the main pattern. More forbidden edges of the main pattern lead to higher likelihood of defects during lithography. That is, higher likelihood of defects of the main pattern leads to higher priority of adding the main auxiliary pattern to the main pattern, and the main auxiliary pattern is the auxiliary pattern closest to the feasible edge, so that the main auxiliary pattern is a pattern that has the greatest impact on the main pattern among the auxiliary patterns. Therefore, in the forms of the present disclosure, the main pattern that easily produces defects is first selected, and the main auxiliary pattern is preferably added to the main pattern that easily produces the defects, so that the proper main auxiliary pattern can be placed on the side portion of the main pattern that easily produced the defects in a targeted manner, to prevent problems such as lack of the main auxiliary pattern around the main pattern that easily produces defects after the auxiliary patterns are added to the entire layout layer or the erroneous addition of the main auxiliary pattern. Therefore, the probability of readjusting the arrangement of the auxiliary patterns after the auxiliary patterns are added to the entire layout layer can be reduced, the time to add the auxiliary patterns can be shortened, and the efficiency of adding the auxiliary patterns can be enhanced. In addition, the probability of defect occurring in the follow-up lithography process can be reduced. Based on the above, it is beneficial to improving the processing result of the optical proximity correction processing.

### BRIEF DESCRIPTION OF THE DRAWINGS

FIG. 1 is a flowchart of an optical proximity correction method according to a form of the present disclosure.

FIG. 2 to FIG. 8 are schematic diagrams corresponding to steps in an optical proximity correction method according to a form of the present disclosure.

FIG. 9 is a functional block diagram of an optical proximity correction system according to a form of the present disclosure.

FIG. 10 is a structure diagram of hardware of a device according to a form of the present disclosure.

### DETAILED DESCRIPTION

It may be learned from the background art that, in the semiconductor manufacturing, with continuous reduction in the design size, the design size gets closer to the limit of a lithography imaging system, and the diffraction effect of light becomes more and more obvious, resulting in optical image degradation of design patterns. The actually formed lithography pattern is seriously distorted relative to the pattern on the mask, and the actual pattern formed by lithography on the silicon wafer is different from the design pattern. This phenomenon is referred to as an optical proximity effect (OPE).

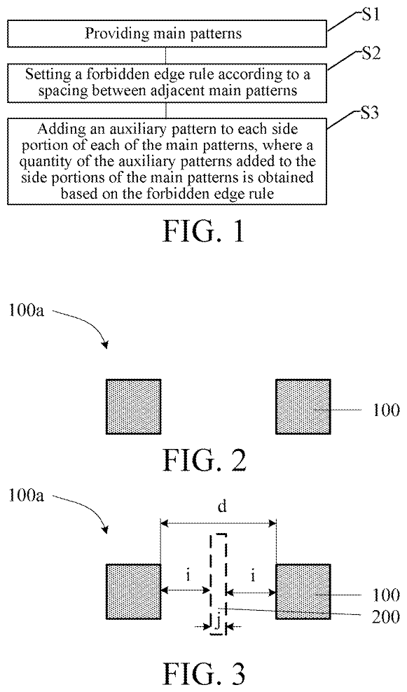

In order to address the technical problem, the present disclosure provides an optical proximity correction method. Referring to FIG. 1, a flowchart of an optical proximity correction method according to a form of the present disclosure is shown.

In this form, the optical proximity correction method includes the following basic steps.

Step S1: Providing main patterns.

Step S2: Setting a forbidden edge rule according to a spacing between adjacent main patterns.

Step S3: Adding auxiliary patterns to side portions of the main patterns, where a quantity of the auxiliary patterns added to the side portions of the main patterns is obtained based on the forbidden edge rule.

In this form, the forbidden edge rule is set according to the spacing between the adjacent main patterns, and the auxiliary patterns are added to the side portions of the main patterns. The quantity of the auxiliary patterns added to the side portions of the main patterns is obtained based on the forbidden edge rule. The auxiliary patterns are usually sub-resolution assist features. That is, the auxiliary pattern is an unexposable pattern. By adding the auxiliary pattern around the main pattern, the imaging deviation generated by different main patterns due to different diffraction effects is reduced. Therefore, the fidelity of patterns can be improved, and the lithography quality of the main pattern can be enhanced. In addition, in this form, the forbidden edge rule is set, and the quantity of the auxiliary patterns added to the side portions of the main patterns is obtained based on the forbidden edge rule, so that the auxiliary patterns can be added according to the actual environmental condition around the main pattern. In this way, a result of the optical proximity correction processing is improved.

To make the objectives, features, and advantages of the present disclosure clearer and more comprehensible, specific forms of the present disclosure are described below in detail with reference to the accompanying drawings.

FIG. 2 to FIG. 8 are schematic diagrams corresponding to steps in an optical proximity correction method according to a form of the present disclosure. Referring to FIG. 2, step S1 of providing main patterns 100 is performed.

Specifically, a layout layer 100a is provided and includes the main patterns 100.

The main patterns 100 in the layout layer 100a are design patterns. The design pattern is a target pattern transferred to a wafer. After optical proximity correction processing is performed on the design pattern, an obtained pattern is used for manufacturing a mask, so that a lithography process is performed by using the mask, to form a corresponding mask pattern on the wafer.

In this form, the layout layer 100a includes a layout layer applicable to a logic device and a SRAM device. In the layout layer of the logic device, the main patterns 100 are randomly distributed. In the layout layer of the SRAM device, the main patterns 100 are distributed regularly. Therefore, during the optical proximity correction processing, when a sub-resolution assist feature technology is used to improve the lithography quality of the main patterns 100 of all-area devices, defects such as lack of the auxiliary patterns around the main pattern 100 or erroneous placement of auxiliary patterns are more likely to occur. Therefore, in this form, the auxiliary patterns are added to the layout layer 100a subsequently by formulating a priority strategy for adding the auxiliary pattern. In this way, the auxiliary patterns can be accurately added to the layout layer of the logic device and the SRAM device, thereby facilitating the improvement in the result of the optical proximity correction processing.

The layout layer in this form includes hole patterns. A shape of the hole pattern is usually a square. Correspondingly, in this form, the main patterns 100 in the layout layer 100a include the hole patterns. A shape of the main pattern 100 includes a square.

In this form, the hole patterns include contact hole patterns or communicating-via patterns. The contact hole patterns are used to form contact holes on a wafer. The contact holes are used to form contact hole plugs. The communicating-via patterns are used to form communicating-vias on the wafer. The communicating-vias are used to form a communicating-via structure. Generally, the contact hole patterns or the communicating-via patterns in the layout layer are randomly distributed, and isolated (ISO) patterns easily occur. For the main patterns 100 that are the ISO patterns, it is especially necessary to fill light with surrounding auxiliary patterns, so as to improve the lithography quality of forming the contact hole patterns or the communicating-via patterns.

It would be appreciated that, for ease of illustration, FIG. 2 only shows two main patterns 100. According to different process requirements, a quantity of the main patterns 100 is not merely limited to two.

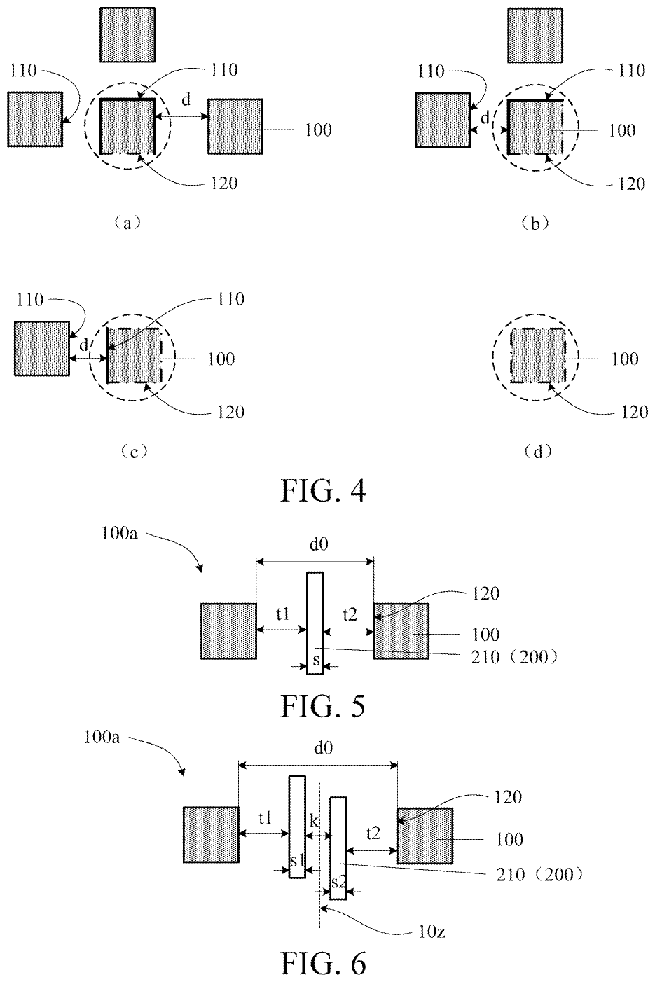

Referring to FIG. 3 and FIG. 4, step S2 of setting the forbidden edge rule according to the spacing between the adjacent main patterns 100 is performed.

Specifically, a spacing d between the adjacent main patterns 100 is acquired. An edge of any of the main patterns 100 at the spacing d from an adjacent main pattern 100 less than a minimum spacing allowing placing the auxiliary pattern is selected as a forbidden edge 110, and remaining edges are used as feasible edges 120. The minimum spacing allowing placing the auxiliary pattern is a sum of a minimum width j of the auxiliary pattern and twice a minimum spacing i between each of the adjacent main patterns 100 and the auxiliary pattern.

During the optical proximity correction process, the sub-resolution assist feature technology is used to enhance the lithographic resolution. By adding the sub-resolution assist features around the main patterns in the layout layer, the imaging deviation of different main patterns due to different diffraction effects is reduced, so that the lithography quality of the main pattern is enhanced, thereby improving the fidelity of the main pattern.

For a strategy of placing the auxiliary patterns in the layout layer 100a, the minimum width j of the auxiliary patterns and the minimum spacing i between each of the adjacent main patterns 100 and the auxiliary pattern are stipulated based on a mask manufacturing rule check (MRC) condition.

It would be appreciated that, for ease of understanding, assuming that an auxiliary pattern 200 exists, FIG. 3 shows, using a dashed box, a schematic diagram of one auxiliary pattern 200 exactly right placed between the adjacent main patterns 100. It may be learned from FIG. 4 that, for the adjacent main patterns 100, a condition under which the auxiliary pattern 200 may be placed on a side portion of one of the main patterns 100 is that a spacing between each of the adjacent auxiliary patterns 200 and the main pattern 100 is greater than or equal to i. A condition under which the auxiliary pattern 200 may be placed on a side portion of another main pattern 100 is also the spacing between each of the adjacent auxiliary patterns 200 and the main pattern 100 is greater than or equal to i, and a width allowing placing the auxiliary pattern 200 needs to be greater than or equal to j. That is, a minimum spacing allowing placing the auxiliary pattern 200 is the sum of the minimum width j of the auxiliary pattern 200 and twice the minimum spacing i between each of the adjacent main patterns 100 and the auxiliary pattern 200. Therefore, for the adjacent main patterns 100, when the spacing d between the adjacent main patterns 100 is greater than or equal to 2i+j, the auxiliary pattern 200 can be placed between the adjacent main patterns 100. When the spacing d between the adjacent main patterns 100 is less than 2i+j, no auxiliary pattern 200 is placed between the adjacent main patterns 100.

In this form, the edge of any of the main patterns 100 at the spacing d from an adjacent main pattern 100 less than the minimum spacing allowing placing the auxiliary pattern is selected as the forbidden edge 110. The forbidden edge 110 is an edge where no auxiliary pattern 200 is placed on the side portion of the main pattern 100. The remaining edges are used as the feasible edges 120. The feasible edges 120 are edges where the auxiliary patterns 200 are placed on the side portions of the main patterns 100.

For ease of understanding, FIG. 4 shows several scenarios in which the main pattern 100 in a dashed circle has the forbidden edge 110 and the feasible edges 120. FIG. 4 only shows the scenario of the adjacent main patterns 100 having the spacing d less than the minimum spacing allowing placing the auxiliary pattern 200. The scenario of the adjacent main patterns 100 having the spacing d greater than or equal to the minimum spacing allowing placing the auxiliary pattern 200 is not shown. For the main patterns 100 in the dashed circle, the forbidden edges 110 are marked by solid lines, and the feasible edges 120 are marked by dot dash lines. Still referring to FIG. 4, the quantity of the feasible edges 120 of each main pattern 100 is acquired.

The quantity of the feasible edges 120 of each main pattern 100 is used as the basis of formulating the priority strategy for adding the auxiliary pattern 200.

FIG. 4 shows several scenarios that the main patterns 100 in the dashed circles have one or more feasible edges 120. In an example, the main pattern 100 in the dashed circle of FIG. 4(a) has one feasible edge 120, the main pattern 100 in the dashed circle of FIG. 4(b) has two feasible edges 120, the main pattern 100 in the dashed circle of FIG. 4(c) has three feasible edges 120, and the main pattern 100 in the dashed circle of FIG. 4(d) has four feasible edges 120.

It would be appreciated that, for the scenario that the main pattern 100 has no feasible edges 120, the auxiliary patterns 200 are not added around the main pattern later. Therefore, the main pattern 100 having no feasible edge 120 is not shown in FIG. 4.

In this form, before the auxiliary pattern 200 is added subsequently, an optimal spacing between the main auxiliary pattern and the main pattern 100 is acquired as a first size based on data of design of experiments (DOE), and an optimal width of the auxiliary pattern 200 is acquired as a second size b.

The main auxiliary pattern is the auxiliary pattern 200 closest to the feasible edge 120.

Different layout layers 100a have different main patterns 100 and different distribution scenarios of the main patterns 100. Therefore, before the auxiliary pattern 200 is actually added, an experiment is required to be further performed on an environment where the auxiliary pattern 200 is added. Finally, based on the data of the DOE, the optimal spacing allowing placing the main auxiliary pattern 210 and the main pattern 100 and the optimal width of the auxiliary pattern 200 are acquired for the corresponding layout layer 100a as the basis of an optimal effect of the subsequent addition of the auxiliary pattern 200.

Referring to FIG. 4 to FIG. 8 together, step S3 of adding the auxiliary patterns 200 to the side portions of the main patterns 100 is performed. The quantity of the auxiliary patterns 200 added to the side portions of the main patterns 100 is obtained based on the forbidden edge rule.

Specifically, in the layout layer 100a, the auxiliary pattern 200 is added to the side portion of the feasible edge 120 of the main pattern 100. The auxiliary pattern 200 includes the main auxiliary pattern 210 closest to the feasible edge 120. The main auxiliary patterns 210 are sequentially added to the side portions of the feasible edges 120 of the main pattern 100 in ascending order of the quantity of the feasible edges 120 of each of the main pattern 100.

In this form, in the step of adding the auxiliary pattern 200 to the side portion of the feasible edge 120 of the main pattern 100, a long side of the auxiliary pattern 200 faces the corresponding feasible edge 120. Therefore, insufficient light filling of the main pattern 100 is avoided.

In this form, the auxiliary pattern 200 includes a scattering bar (SBar). The main pattern 100 is an exposable pattern. The auxiliary pattern 200 is an unexposable pattern. Therefore, the auxiliary pattern 200 is the SBar. A line width of the auxiliary pattern 200 is greater than or equal to a minimum line width of a mask writing rule and is less than or equal to resolution of a lithography process, so that the auxiliary pattern 200 can be written into a template but cannot be exposed.

By disposing the SBar around the main pattern 100, light intensity contrast is improved, and an edge placement error (EPE) is reduced, and a focal depth is increased. As a result, a lithography process window is enhanced.

In this form, the ascending order of the quantity of the feasible edges 120 of the main pattern 100 is descending order of the quantity of the forbidden edges 110 of the main pattern 100. More forbidden edges 110 of the main pattern 100 lead to higher likelihood of defects during lithography. That is, higher likelihood of defects of the main pattern 100 leads to higher priority of adding the main auxiliary pattern 210 to the main pattern 100, and the main auxiliary pattern 210 is the auxiliary pattern 200 closest to the feasible edge 120, and thus the main auxiliary pattern 210 is a pattern that has the greatest impact on the main pattern 100 among the auxiliary patterns 200. Therefore, in this form, the main pattern 100 that easily produces defects is first selected, and the main auxiliary pattern 210 is added to the main pattern 100 that easily produces the defects, to prevent problems such as lack of the main auxiliary pattern 210 around the main pattern 100 that easily produces defects after the auxiliary patterns 200 are added to the entire layout layer 100a or the erroneous addition of the main auxiliary pattern 210. Therefore, the probability of readjusting the arrangement of the auxiliary patterns 200 after the auxiliary patterns 200 are added to the entire layout layer 100a can be reduced, the time to add the auxiliary patterns 200 can be shortened, and the efficiency of adding the auxiliary patterns 200 can be enhanced. In addition, the probability of defect occurring in the follow-up lithography process can be reduced. Based on the above, it is beneficial to improving the processing result of the optical proximity correction processing.

As shown in FIG. 4, in this form, the main patterns 100 in the dashed circle are used as an example. The main auxiliary patterns 210 are sequentially added to the side portions of the feasible edges 120 in FIG. 4(a), FIG. 4(b), FIG. 4(c), and FIG. 4(d) in ascending order of the quantity of the feasible edges 120 of each of the main patterns 100.

In this form, the main auxiliary patterns 210 are added to the main patterns 100 having a same quantity of the feasible edges 120.

Environments for adding the main auxiliary patterns 210 around the main patterns 100 having the same quantity of the feasible edges 120 are similar. Therefore, a same strategy can be adopted to add the main auxiliary patterns 210, so as to enhance the efficiency of adding the auxiliary patterns 200.

Referring to FIG. 5 to FIG. 8, the step of sequentially adding the main auxiliary patterns 210 to the side portions of the feasible edges 120 of the main pattern 100 includes: determining whether the side portions of the feasible edges 120 of the main pattern 100 have other adjacent feasible edges 120.

It is determined whether the side portions of the feasible edges 120 of the main pattern 100 have other adjacent feasible edges 120, to classify different environments for adding the main auxiliary patterns 210.

Specifically, referring to FIG. 5 to FIG. 7, when the feasible edges 120 of the main pattern 100 have the adjacent feasible edges 120, a spacing between the adjacent feasible edges 120 is detected.

A spacing d0 between the adjacent feasible edges 120 is detected for determining quantities and classifying positions allowing placing the main auxiliary patterns 210 between the adjacent feasible edges 120.

It would be appreciated that, adjacent sides of the adjacent main patterns 100 are the feasible edges 120, and then the spacing d between the adjacent main patterns 100 is greater than or equal to 2i+j. As a result, the spacing d0 between the adjacent feasible edges 120 is greater than or equal to 2i+j.

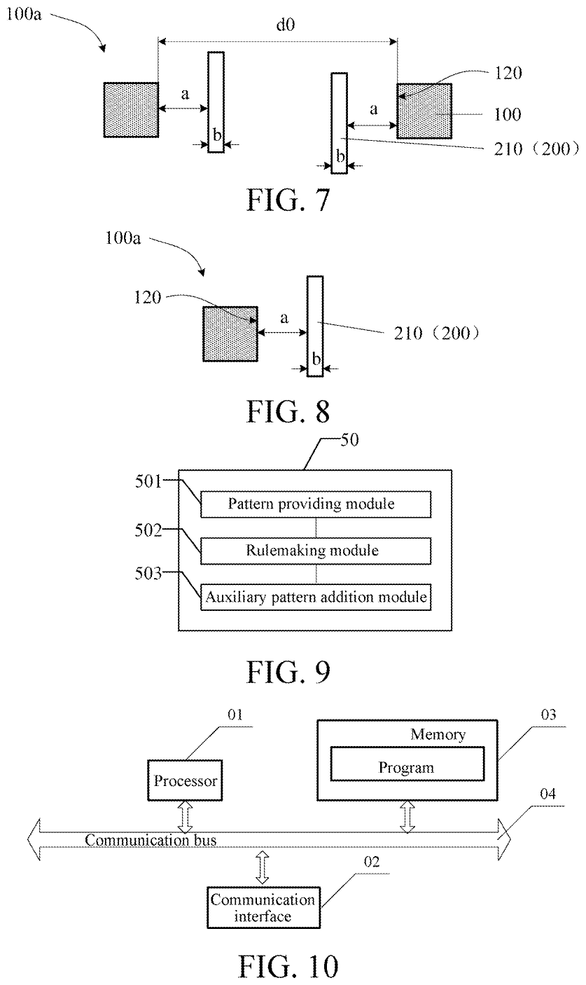

Specifically, as shown in FIG. 5, one main auxiliary pattern 210 is placed between the adjacent feasible edges 120 when the spacing d0 between the adjacent feasible edges 120 is less than a first spacing. As shown in FIG. 6 and FIG. 7, two main auxiliary patterns 210 are placed between the adjacent feasible edges 120 when the spacing d0 between the adjacent feasible edges 120 is greater than or equal to the first spacing. The first spacing is a sum of twice the minimum spacing i between adjacent auxiliary patterns 200 and the main pattern 100, twice the minimum width j of the auxiliary pattern 200, and a minimum spacing k between the adjacent auxiliary patterns 200. That is, the first spacing is equal to 2i+2j+k.

A strategy of placing the auxiliary pattern in the layout layer 100a further stipulates the minimum spacing k between the adjacent auxiliary patterns based on the MRC condition.

It would be appreciated that, for the adjacent feasible edges 120, a condition under which the main auxiliary pattern 210 may be placed on a side portion of one of the feasible edges 120 is that a spacing between the main auxiliary pattern 210 and the feasible edge 120 is greater than or equal to i.

A condition under which the main auxiliary pattern 210 may be placed on the side portion of another feasible edge 120 is also that the spacing between the main auxiliary pattern 210 and the feasible edge 120 is greater than or equal to i, and a width allowing placing the main auxiliary pattern 210 is required to be greater than or equal to j. A condition for placing two main auxiliary patterns 210 further includes that the spacing between the two adjacent main auxiliary patterns 210 is k. That is, the minimum spacing allowing placing the two main auxiliary patterns 210 is the sum of twice the minimum spacing i between each of the adjacent auxiliary patterns 200 and the main pattern 100, twice the minimum width j of the auxiliary pattern 200, and the minimum spacing k between the adjacent auxiliary patterns 200. Therefore, for the adjacent feasible edges 120, when the spacing d0 between the adjacent feasible edges 120 is greater than or equal to 2i+2j+k, the two main auxiliary patterns 210 can be placed between the adjacent feasible edges 120. When the spacing d0 between the adjacent feasible edges 120 is less than 2i+2j+k, only one main auxiliary pattern 210 can be placed between the adjacent feasible edges 120, that is, the first spacing is 2i+2j+k.

In this form, in the step of placing the main auxiliary pattern 210 between the adjacent feasible edges 120, the spacings between the adjacent feasible edges 120 and the main auxiliary pattern 210 are both equal.

The spacings between the adjacent feasible edges 120 and the main auxiliary pattern 210 are both equal, so that the main auxiliary pattern 210 can uniformly fill light for the adjacent main patterns 100. Therefore, the uniformity of the lithography quality of the main pattern 100 in the layout layer 100a can be improved. In particular, for a scenario that the spacing between the adjacent feasible edges 120 is insufficient to place the main auxiliary pattern 210 at an optimal position, the main auxiliary patterns 210 are directly placed at positions at the same spacing from the feasible edges 120. In this way, this can help avoid the conflict between the main auxiliary patterns 210 as a result of the main auxiliary patterns 210 being placed at the optimal position for two adjacent feasible edges 120. Special cleaning is subsequently required to be performed on the main auxiliary patterns 210 conflicting with each other, which easily causes the problems such as lack of the main auxiliary patterns 210 around the main pattern 210, erroneous placement of the main auxiliary patterns 210, or the like.

Specifically, referring to FIG. 5, the step of placing one main auxiliary pattern 210 between the adjacent feasible edges 120 includes: placing one main auxiliary pattern 210 between the adjacent feasible edges 120. Distances t1 and t2 between the main auxiliary pattern 210 and the adjacent feasible edges 120 on two sides are equal, and a width s of the main auxiliary pattern 210 is a second size b.

Since the distances t1 and t2 between the main auxiliary pattern 210 and the adjacent feasible edges 120 on two sides are equal, the spacings between the adjacent feasible edges 120 and the main auxiliary pattern 210 are both equal. The width s of the main auxiliary pattern 210 is the second size b, so that the width s is set as an optimal width when the main auxiliary pattern 210 is designed.

The width s of the main auxiliary pattern 210 has great impact on the light filling effect of the adjacent main patterns 210. Therefore, for the width s of the main auxiliary pattern 210 and the spacing between the main auxiliary pattern 210 and the adjacent feasible edges 120, priority is given to ensuring that the width s of the main auxiliary pattern 210 is optimal, that is, the second size b.

In this form, a distance between the main auxiliary pattern 210 and each of the adjacent feasible edges 120 is acquired as a first distance t0.

The first distance t0 is acquired as the basis for whether to adjust the main auxiliary pattern 210 subsequently.

In this form, it is determined whether the first distance t0 is greater than or equal to the minimum spacing i between each of the adjacent main patterns 100 and the auxiliary pattern 200.

Specifically, when the first distance t0 is less than the minimum spacing i between each of the adjacent main patterns 100 and the auxiliary pattern 200, the width s of the main auxiliary pattern 210 is reduced, and the step of acquiring the distances between the main auxiliary pattern 210 and the adjacent feasible edges 120 is performed.

When the first distance t0 is less than the minimum spacing i between each of the adjacent main patterns 100 and the auxiliary pattern 200, the first distance t0 does not satisfy the MRC condition. Therefore, the width s of the main auxiliary pattern 210 is reduced from two sides of the main auxiliary pattern 210 to the middle, so that the spacings between the main auxiliary pattern 210 and the adjacent feasible edges 120 on two sides are kept the same all the time. In addition, the first distances t0 from two sides of the main auxiliary pattern 210 can be increased, to cause the first distance t0 to satisfy the MRC condition.

In this form, in the step of reducing the width s of the main auxiliary pattern 210, the width is incrementally decreased by a first preset size.

In the step of reducing the width s of the main auxiliary pattern 210, the width is incrementally decreased by a same size, so that the width s of the main auxiliary pattern 210 is decreased uniformly and regularly. Algorithms for reducing the width s of the main auxiliary pattern 210 each time are unified. A method for adjusting the width s of the main auxiliary pattern 210 by a loop iteration is simplified. Therefore, the step of adding the auxiliary pattern 200 is prevented from being too tedious and confusing, which facilitates stable implementation of the first distance t0 being greater than or equal to the minimum spacing i between each of the adjacent main patterns 100 and the auxiliary pattern 200.

It would be appreciated that, a first preset size should be neither excessively large nor excessively small. If the first preset size is excessively large, a step size of the loop iteration is excessively large, and the width s of the main auxiliary pattern 210 is reduced too much each time, which is likely to cause the finally obtained width s of the main auxiliary pattern 210 to be excessively small. As a result, it is likely to cause the insufficient light filling of the main auxiliary pattern 210 to the adjacent main patterns 100, and cause the finally obtained first distance t0 to be much greater than the minimum spacing i between each of the adjacent main patterns 100 and the auxiliary pattern 200, resulting in an unnecessary waste of space of the layout layer 100a. If the first preset size is excessively small, the step size of the loop iteration is excessively small, and the width s of the main auxiliary pattern 210 is reduced too little each time. In this way, it is likely to cause an excessively large number of loop iterations and prolong the time of adding the auxiliary pattern 200, which increases the unnecessary time and operation costs. Therefore, in this form, the first preset size ranges from 0.2 nm to 2 nm. For example, the first preset size is 0.6 nm, 1 nm, or 1.5 nm.

In this form, when the first distance t0 is greater than or equal to the minimum spacing i between each of the adjacent main patterns 100 and the auxiliary pattern 200, the step of placing one main auxiliary pattern 210 between the adjacent feasible edges 120 is performed.

When the first distance t0 is greater than or equal to the minimum spacing i between each of the adjacent main patterns 100 and the auxiliary pattern 200, the first distance t0 satisfies the MRC condition, and the width of the main auxiliary pattern 210 being the second size b also satisfies the MRC condition. Therefore, the step of placing one main auxiliary pattern 210 between the adjacent feasible edges 120 is performed.

It would be appreciated that, when the first distance t0 is greater than the first size a, although the first distance t0 is already greater than the optimal spacing between the main auxiliary pattern 210 and the main pattern 100, in order to cause the main auxiliary pattern 210 not to be exposed, the width s of the main auxiliary pattern 210 is less than or equal to the resolution of the lithography process. Therefore, the width s of the main auxiliary pattern 210 should not be excessively large. The width s of the main auxiliary pattern 210 is the second size b, which is already the optimal size and is sufficient to fill the main pattern 100 with light, improve the light intensity contrast, and enhance the lithography process window. Therefore, when the first distance t0 is greater than the first size a, the step of placing one main auxiliary pattern 210 between the adjacent feasible edges 120 is still performed.

Referring to FIG. 6 and FIG. 7, the step of placing two main auxiliary patterns 210 between the adjacent feasible edges 120 includes: determining whether the spacing d0 between the adjacent feasible edges 120 is less than a second spacing. The second spacing is a sum of twice the first size a, twice the second size b, and the minimum spacing k between the adjacent auxiliary patterns 200.

The second spacing is a classification basis for whether the two main auxiliary patterns 210 placed between the adjacent feasible edges 120 may be placed at an optimal position.

It would be appreciated that, for the adjacent feasible edges 120, a condition under which the main auxiliary pattern 210 may be placed at the optimal position on the side portion of one of the feasible edges 120 is that the spacing between the main auxiliary pattern 210 and the feasible edge 120 is greater than or equal to b. A condition under which the main auxiliary pattern 210 may be placed at the optimal position on the side portion of another feasible edge 120 is also that the spacing between the main auxiliary pattern 210 and the feasible edge 120 is greater than or equal to b, and an optimal width allowing placing the main auxiliary patterns 210 is a. In addition, a condition of placing two main auxiliary patterns 210 further includes that the spacing between the two adjacent main auxiliary patterns 210 is k. That is, the minimum spacing allowing placing the two main auxiliary patterns 210 with the optimal width at the optimal position is the sum of twice the first size a, twice the second size b, and the minimum spacing k between the adjacent auxiliary patterns 200. Therefore, for the adjacent feasible edges 120, when the spacing d0 between the adjacent feasible edges 120 is greater than or equal to 2a+2b+k, the two main auxiliary patterns 210 with the optimal width can be placed at the optimal position between the adjacent feasible edges 120. When the spacing d0 between the adjacent feasible edges 120 is less than 2a+2b+k, a position at which the main auxiliary pattern 210 is placed between the adjacent feasible edges 120 or the width s of the main auxiliary pattern 210 needs to be adjusted, that is, the second spacing is 2a+2b+k.

Specifically, referring to FIG. 6, when the spacing d0 between the adjacent feasible edges 120 is less than the second spacing, one main auxiliary pattern 210 is placed on each of two sides of a center line 10z of the spacing between the adjacent feasible edges 120. A spacing between the two main auxiliary patterns 210 is the minimum spacing k between the adjacent auxiliary patterns 200, distances between the two main auxiliary patterns 210 and the center lines 10z are equal, and the width s of the main auxiliary pattern 210 is the second size b. The width s of the main auxiliary pattern 210 includes a width s1 and a width s2 of the two main auxiliary patterns 210.

One main auxiliary pattern 210 is placed on each of the two sides of the center line 10z of the spacing between the adjacent feasible edges 120, and the distances between the two main auxiliary patterns 210 and the center line 10z are equal. As a result, the distances t1 and t2 between the main auxiliary pattern 210 and the adjacent feasible edges 120 on two sides are equal. Therefore, the spacings between the adjacent feasible edges 120 and the main auxiliary pattern 210 are both equal. The widths s1 and s2 of the main auxiliary patterns 210 are both the second size b, so that the width s of the main auxiliary pattern is set as an optimal width when the main auxiliary pattern 210 is designed.

The width s of the main auxiliary pattern 210 has great impact on the light filling effect of the adjacent main patterns 210. Therefore, for the width s of the main auxiliary pattern 210 and the spacing between the main auxiliary pattern 210 and the adjacent feasible edges 120, priority is given to ensuring that the width s of the main auxiliary pattern 210 is optimal, that is, the second size b.

In this form, a distance between the main auxiliary pattern 210 and each of the adjacent feasible edges 120 is acquired as a second distance T0.

The second distance T0 is acquired as the basis for whether to adjust the main auxiliary pattern 210 subsequently.

In this form, it is determined whether the second distance T0 is greater than or equal to the minimum spacing i between each of the adjacent main patterns 100 and the auxiliary pattern 200.

Specifically, when the second distance T0 is less than the minimum spacing i between each of the adjacent main patterns 100 and the auxiliary pattern 200, the widths s1 and s2 of the main auxiliary patterns 210 are reduced, and the step of acquiring the distances between the main auxiliary pattern 210 and the adjacent feasible edges 120 is performed.

When the second distance T0 is less than the minimum spacing i between each of the adjacent main patterns 100 and the auxiliary pattern 200, the second distance T0 does not satisfy the MRC condition. Therefore, the widths s1 and s2 of the two main auxiliary patterns 210 are reduced from two sides of each of the main auxiliary patterns 210 to the middle, so that the spacings between the main auxiliary pattern 210 and the adjacent feasible edges 120 on two sides are kept the same all the time. In addition, the second distances TO from two sides of the main auxiliary pattern 210 can be increased, to cause the second distance T0 to satisfy the MRC condition.

In this form, in the step of reducing the widths s1 and s2 of the two main auxiliary patterns 210, the widths of the two main auxiliary patterns 210 are incrementally decreased by a second preset size.

In the step of reducing the widths s1 and s2 of the two main auxiliary patterns 210, the widths of the two main auxiliary patterns 210 are incrementally decreased by a same size, so that the widths s1 and s2 of the two main auxiliary patterns 210 are decreased uniformly and regularly. Algorithms for reducing the widths s1 and s2 of the two main auxiliary patterns 210 each time are unified. A method for adjusting the width s of the main auxiliary pattern 210 by a loop iteration is simplified. Therefore, the step of adding the auxiliary pattern 200 is prevented from being too tedious and confusing, which facilitates stable implementation of the second distance T0 being greater than or equal to the minimum spacing i between each of the adjacent main patterns 100 and the auxiliary pattern 200.

It would be appreciated that, a second preset size should be neither excessively large nor excessively small. If the second preset size is excessively large, a step size of the loop iteration is excessively large, and the widths s1 and s2 of the two main auxiliary patterns 210 are reduced too much each time, which is likely to cause the finally obtained widths s1 and s2 of the two main auxiliary patterns 210 to be excessively small. As a result, it is likely to cause the insufficient light filling of the main auxiliary pattern 210 to the adjacent main patterns 100, and cause the finally obtained second distance T0 to be much greater than the minimum spacing i between each of the adjacent main patterns 100 and the auxiliary pattern 200, resulting in an unnecessary waste of space of the layout layer 100a. If the second preset size is excessively small, the step size of the loop iteration is excessively small, and the widths s1 and s2 of the two main auxiliary patterns 210 are reduced too little each time. In this way, it is likely to cause an excessively large number of loop iterations and prolong the time of adding the auxiliary pattern 200, which increases the unnecessary time and operation costs. Therefore, in this form, the second preset size ranges from 0.2 nm to 2 nm. For example, the second preset size is 0.6 nm, 1 nm, or 1.5 nm.

In this form, when the second distance T0 is greater than or equal to the minimum spacing i between each of the adjacent main patterns 100 and the auxiliary pattern 200, the step of placing two main auxiliary patterns 210 between the adjacent feasible edges 120 is performed.

When the second distance T0 is greater than or equal to the minimum spacing i between each of the adjacent main patterns 100 and the auxiliary pattern 200, the second distance T0 satisfies the MRC condition, and the width of the main auxiliary pattern 210 being the second size b also satisfies the MRC condition. Therefore, the step of placing two main auxiliary patterns 210 between the adjacent feasible edges 120 is performed.

Referring to FIG. 7, when the spacing d0 between the adjacent feasible edges 120 is greater than or equal to the second spacing, the main auxiliary pattern 210 adjacent to the corresponding feasible edge 120 is placed at a position at a distance of the first size a from any of the feasible edges 120, and the width s of the main auxiliary pattern 210 is the second size b.

When the spacing d0 between the adjacent feasible edges 120 is greater than or equal to the second spacing, the optimal position between the adjacent feasible edges 120 is sufficient to place the main auxiliary pattern 210 with the optimal width. Therefore, the main auxiliary pattern 210 adjacent to the corresponding feasible edge 120 is placed at a position at a distance of the first size a from any of the feasible edges 120, and the width s of the main auxiliary pattern 210 is the second size b.

Referring to FIG. 8, when no adjacent main patterns 100 are present on the side portion of the feasible edge 120 of the main pattern 100, one main auxiliary pattern 210 is placed on the side portion of the feasible edge 120.

When no adjacent main patterns 100 are present on the side portion of the feasible edge 120 of the main pattern 100, one main auxiliary pattern 210 may be placed on the side portion of the feasible edge 120.

In this form, when no adjacent main patterns 100 are present on the side portion of the feasible edge 120 of the main pattern 100, in the step of placing one main auxiliary pattern 210 on the side portion of the feasible edge 120, the main auxiliary pattern 210 is placed at a position at a distance of the first size a from the feasible edge 120, and the width of the main auxiliary pattern 210 is the second size b.

When no adjacent main patterns 100 are present on the side portion of the feasible edge 120 of the main pattern 100, the optimal position of the side portion of the feasible edge 120 is sufficient to place the main auxiliary pattern 210 with the optimal width. Therefore, the main auxiliary pattern 210 is placed at a position at a distance of the first size a from the feasible edge 120, and the width of the main auxiliary pattern 210 is the second size b.

Referring to FIG. 7 and FIG. 8, as shown in FIG. 7, when the spacing d0 between the adjacent feasible edges 120 is greater than or equal to a third spacing, alternatively, as shown in FIG. 8, when no adjacent main patterns 100 are present on the side portion of the feasible edge 120 of the main pattern 100, in the step of adding the auxiliary pattern 200 to the side portion of the feasible edge 120 of the main pattern 100, after the main auxiliary patterns 210 are sequentially added to the side portions of the feasible edges 120 of the main pattern 100,

other auxiliary patterns 200 are placed on a side of the main auxiliary pattern 210 away from the feasible edge 120. The third spacing is a sum of twice the first size a, twice the second size b, twice the minimum spacing k between the adjacent auxiliary patterns, and the minimum width j of the auxiliary pattern, that is, the third spacing equals 2a+2b+2k+j.

It would be appreciated that, the main auxiliary pattern 210 is the auxiliary pattern 200 that has the greatest impact on the main pattern 100. Therefore, the other auxiliary patterns 200 are placed when it is ensured that the main auxiliary pattern 210 is placed at the optimal position and has the optimal width.

Therefore, for the adjacent feasible edges 120, a condition under which the main auxiliary pattern 210 may be placed at the optimal position on the side portion of one of the feasible edges 120 is that the spacing between the main auxiliary pattern 210 and the feasible edge 120 is greater than or equal to b. A condition under which the main auxiliary pattern 210 may be placed at the optimal position on the side portion of another feasible edge 120 is also that the spacing between the main auxiliary pattern 210 and the feasible edge 120 is greater than or equal to b, and an optimal width allowing placing the main auxiliary patterns 210 is a. In addition, a condition of placing three auxiliary patterns 200 includes that the spacing between two adjacent auxiliary patterns 200 is k, and a width allowing placing the third auxiliary pattern 200 should be greater than or equal to j. That is, the minimum spacing d0 allowing placing other auxiliary patterns 200 is the sum of twice the first size a, twice the second size b, the minimum spacing k between the adjacent auxiliary patterns, and the minimum width j of the auxiliary pattern. Therefore, for the adjacent feasible edges 120, when the spacing d0 between the adjacent feasible edges 120 is greater than or equal to 2a+2b+2k+j, the other auxiliary patterns 200 can be placed between the adjacent feasible edges 120, that is, the third spacing is 2a+2b+2k+j.

When the spacing d0 between the adjacent feasible edges 120 is greater than or equal to the third spacing, or when no adjacent main patterns 100 are present on the side portion of the feasible edge 120 of the main pattern 100, there is also space allowing placing the other auxiliary patterns 200 after the main auxiliary pattern 210 is placed on the side portion of the feasible edge 120, so as to further fill light for the main pattern 100. Therefore, the imaging deviation generated by different main patterns 100 due to different diffraction effects is reduced, the lithography quality of the main pattern 100 is enhanced, and the fidelity of the main pattern 100 is improved.

It would be appreciated that, in this form, after the auxiliary pattern 200 is added to the side portion of the feasible edge 120 of the main pattern 100, optical proximity correction processing is performed on the main pattern 100.

In other forms, before the auxiliary pattern is added to the side portion of the feasible edge of the main pattern, the optical proximity correction processing may further be performed on the main pattern. That is, after the optical proximity correction processing is performed on the main pattern, the auxiliary pattern is added to the side portion of the feasible edge of the main pattern.

The present disclosure further provides an optical proximity correction system. FIG. 9 is a functional block diagram of a form of an optical proximity correction system according to the present disclosure.

In this form, the optical proximity correction system 50 includes: a pattern providing module 501, configured to provide main patterns; a rulemaking module 502, configured to set a forbidden edge rule according to a spacing between adjacent main patterns; and an auxiliary pattern addition module 504, configured to add an auxiliary pattern to each side portion of each of the main patterns. A quantity of the auxiliary patterns added to the side portions of the main patterns is obtained based on the forbidden edge rule.

The pattern providing module 501 is configured to provide the main patterns.

Specifically, the pattern providing module 501 includes a layout layer providing unit configured to provide a layout layer that includes the main patterns.

The main patterns in the layout layer are design patterns. The design pattern is a target pattern transferred to a wafer. After optical proximity correction processing is performed on the design pattern, an obtained pattern is used for manufacturing a mask, so that a lithography process is performed by using the mask, to form a corresponding mask pattern on the wafer.

In this form, the layout layer includes a layout layer applicable to a logic device and a SRAM device.

In the layout layer of the logic device, the main patterns are randomly distributed. In the layout layer of the SRAM device, the main patterns are distributed regularly. Therefore, during the optical proximity correction processing, when a sub-resolution assist feature technology is used to improve the lithography quality of the main patterns of all-area devices, defects such as lack of the auxiliary patterns around the main pattern or erroneous placement of auxiliary patterns are more likely to occur. Therefore, in this form, the auxiliary patterns are added to the layout layer subsequently by formulating a priority strategy for adding the auxiliary pattern. In this way, the auxiliary patterns can be accurately added to the layout layer of the logic device and the SRAM device, thereby facilitating the improvement in the result of the optical proximity correction processing.

In this form, the layout layer includes hole patterns. A shape of the hole pattern is usually a square. Correspondingly, in this form, the main patterns in the layout layer include the hole patterns. A shape of the main pattern includes a square.

In this form, the hole patterns include contact hole patterns or communicating-via patterns.

The contact hole patterns are used to form contact holes on a wafer. The contact holes are used to form contact hole plugs. The communicating-via patterns are used to form communicating-vias on the wafer. The communicating-vias are used to form a communicating-via structure. Generally, the contact hole patterns or the communicating-via patterns in the layout layer are randomly distributed, and isolated patterns easily occur. For the main patterns that are the ISO patterns, it is especially necessary to fill light with surrounding auxiliary patterns, so as to improve the lithography quality of forming the contact hole patterns or the communicating-via patterns.

The rulemaking module 502 includes: a spacing measurement unit, configured to: acquire a spacing d between the adjacent main patterns, and select, as a forbidden edge, an edge of any of the main patterns at a spacing d from an adjacent main patterns less than a minimum spacing allowing placing the auxiliary patterns, and use remaining edges as feasible edges. The minimum spacing allowing placing the auxiliary patterns is a sum of a minimum width j of the auxiliary pattern and twice a minimum spacing i between each of the adjacent main patterns and the auxiliary pattern.

During the optical proximity correction processing, the sub-resolution assist feature technology is used to enhance the lithographic resolution. By adding the sub-resolution assist features around the main pattern in the layout layer, the imaging deviation of different main patterns due to different diffraction effects is reduced, so that the lithography quality of the main pattern is enhanced, thereby improving the fidelity of the main pattern.

For a strategy of placing the auxiliary patterns in the layout layer, the minimum width j of the auxiliary patterns and the minimum spacing i between each of the adjacent main patterns and the auxiliary pattern are stipulated based on the MRC condition.

It would be appreciated that, for the adjacent main patterns, a condition under which the auxiliary pattern may be placed on a side portion of one of the main patterns is that a spacing between each of the adjacent auxiliary patterns and the main pattern is greater than or equal to i. A condition under which the auxiliary pattern may be placed on a side portion of another main pattern is also the spacing between each of the adjacent auxiliary patterns and the main pattern is greater than or equal to i, and a width allowing placing the auxiliary pattern needs to be greater than or equal to j. That is, a minimum spacing allowing placing the auxiliary pattern is the sum of the minimum width j of the auxiliary pattern and twice the minimum spacing i between each of the adjacent main patterns and the auxiliary pattern. Therefore, for the adjacent main patterns, when the spacing d between the adjacent main patterns is greater than or equal to 2i+j, the auxiliary pattern can be placed between the adjacent main patterns. When the spacing d between the adjacent main patterns is less than 2i+j, no auxiliary pattern is placed between the adjacent main patterns.

In this form, the edge of any of the main patterns at the spacing d from an adjacent main pattern less than the minimum spacing allowing placing the auxiliary pattern is selected as the forbidden edge. The forbidden edge is an edge where no auxiliary pattern is placed on the side portion of the main pattern. The remaining edges are used as the feasible edges. The feasible edges are edges where the auxiliary patterns are placed on the side portions of the main patterns.

The rulemaking module 502 further includes a quantity acquisition unit configured to acquire a quantity of the feasible edges of each of the main patterns.

The quantity of the feasible edges of the main pattern is used as the basis of formulating the priority strategy for adding the auxiliary patterns.

In this form, before the auxiliary pattern is added subsequently, an optimal spacing between the main auxiliary pattern and the main pattern is acquired as a first size a based on data of DOEs, and an optimal width of the auxiliary pattern is acquired as a second size b.

The main auxiliary pattern is the auxiliary pattern closest to the feasible edge.

Different layout layers have different main patterns and different distribution scenarios of the main patterns. Therefore, before the auxiliary pattern is added subsequently, an experiment is required to be further performed on an environment where the auxiliary pattern is added. Finally, based on the data of the DOE, the optimal spacing allowing placing the main auxiliary pattern and the main pattern and the optimal width of the auxiliary pattern are acquired for the corresponding layout layer as the basis of an optimal effect of the subsequent addition of the auxiliary pattern.

The auxiliary pattern addition module 503 is further configured to, in the layout layer, add the auxiliary pattern on each side portion of each of the feasible edges of the main pattern, where the auxiliary patterns include a main auxiliary pattern closest to the feasible edge, and sequentially add the main auxiliary pattern to each side portion of each of the feasible edges of the main pattern in ascending order of the quantity of the feasible edges of each of the main patterns.

In this form, a long side of the auxiliary pattern faces the corresponding feasible edge. Therefore, insufficient light filling of the main pattern is avoided.

In this form, the main pattern is an exposable pattern. The auxiliary pattern is an unexposable pattern. Therefore, the auxiliary pattern is the SBar. A line width of the auxiliary pattern is greater than or equal to a minimum line width of a mask writing rule and is less than or equal to resolution of a lithography process, so that the auxiliary pattern can be written into a template but cannot be exposed.

By disposing the SBar around the main pattern, light intensity contrast is improved, and the EPE is reduced, and a focal depth is increased, so that a lithography process window is enhanced.

In this form, the ascending order of the quantity of the feasible edges of the main pattern is descending order of a quantity of the forbidden edges of the main pattern. More forbidden edges of the main pattern lead to higher likelihood of defects during lithography. That is, higher likelihood of defects of the main pattern leads to higher priority of adding the main auxiliary pattern to the main pattern, and the main auxiliary pattern is the auxiliary pattern closest to the feasible edge, so that the main auxiliary pattern is a pattern that has the greatest impact on the main pattern among the auxiliary patterns. Therefore, in the forms of the present disclosure, the main pattern that easily produces defects is first selected, and the main auxiliary pattern is preferably added to the main pattern that easily produces the defects, to prevent problems such as lack of the main auxiliary patterns around the main pattern that easily produces defects after the auxiliary pattern is added to the entire layout layer or the erroneous addition of the main auxiliary pattern. Therefore, the probability of readjusting the arrangement of the auxiliary patterns after the auxiliary patterns are added to the entire layout layer can be reduced, the time to add the auxiliary patterns can be shortened, and the efficiency of adding the auxiliary patterns can be enhanced. In addition, the probability of defect occurring in the follow-up lithography process can be reduced. Based on the above, it is beneficial to improving the processing result of the optical proximity correction processing.

In this form, the main auxiliary patterns are added to the main patterns having a same quantity of the feasible edges.

Environments for adding the main auxiliary patterns around the main patterns having the same quantity of the feasible edges are similar. Therefore, a same strategy can be adopted to add the main auxiliary patterns, so as to enhance the efficiency of adding the auxiliary patterns.

In this form, it is determined whether the side portions of the feasible edges of the main pattern have other adjacent feasible edges.

It is determined whether the side portions of the feasible edges of the main pattern have other adjacent feasible edges, to classify different environments for adding the main auxiliary patterns.

Specifically, when the feasible edges of the main pattern have adjacent feasible edges, a spacing between the adjacent feasible edges is detected.

A spacing d0 between the adjacent feasible edges is detected for determining quantities and classifying positions allowing placing the main auxiliary patterns between the adjacent feasible edges.

It would be appreciated that, adjacent sides of the adjacent main patterns are the feasible edges, and then the spacing d between the adjacent main patterns is greater than or equal to 2i+j, so that the spacing d0 between the adjacent feasible edges is greater than or equal to 2i+j.

Specifically, one main auxiliary pattern is placed between the adjacent feasible edges when the spacing d0 between the adjacent feasible edges is less than a first spacing. Two main auxiliary patterns are placed between the adjacent feasible edges when the spacing d0 between the adjacent feasible edges is greater than or equal to the first spacing. The first spacing is a sum of twice the minimum spacing i between adjacent auxiliary patterns and the main pattern, twice the minimum width j of the auxiliary pattern, and the minimum spacing k between the adjacent auxiliary patterns. That is, the first spacing is equal to 2i+2j+k.

A strategy of placing the auxiliary pattern in the layout layer further stipulates the minimum spacing k between the adjacent auxiliary patterns based on the MRC condition.

It would be appreciated that, for the adjacent feasible edges, a condition under which the main auxiliary pattern may be placed on the side portion of one of the feasible edges is that the spacing between the main auxiliary pattern and the feasible edge is greater than or equal to i. A condition under which the main auxiliary pattern may be placed on the side portion of another feasible edge is also that the spacing between the main auxiliary pattern and the feasible edge is greater than or equal to i, and a width allowing placing the main auxiliary pattern is required to be greater than or equal to j. A condition of placing two main auxiliary patterns further includes that the spacing between the two adjacent main auxiliary patterns is k. That is, the minimum spacing allowing placing the two main auxiliary patterns is the sum of twice the minimum spacing i between the adjacent auxiliary patterns and the main pattern, twice the minimum width j of the auxiliary pattern, and the minimum spacing k between the adjacent auxiliary patterns. Therefore, for the adjacent feasible edges, when the spacing d0 between the adjacent feasible edges is greater than or equal to 2i+2j+k, the two main auxiliary patterns can be placed between the adjacent feasible edges. When the spacing d0 between the adjacent feasible edges is less than 2i+2j+k, only one main auxiliary pattern can be placed between the adjacent feasible edges, that is, the first spacing is 2i+2j+k.

In this form, in the step of placing the main auxiliary pattern between the adjacent feasible edges, the spacings between the adjacent feasible edges and the main auxiliary pattern are both equal.

The spacings between the adjacent feasible edges and the main auxiliary pattern are both equal, so that the main auxiliary pattern can uniformly fill light for the adjacent main patterns. Therefore, the uniformity of the lithography quality of the main pattern in the layout layer can be improved. In particular, for a scenario that the spacing between the adjacent feasible edges is insufficient to place the main auxiliary pattern at an optimal position, the main auxiliary patterns are directly placed at positions at the same spacing from the feasible edges. In this way, this can help avoid the conflict between the main auxiliary patterns as a result of the main auxiliary patterns being placed at the optimal position for two adjacent feasible edges. Special cleaning is subsequently required to be performed on the main auxiliary patterns conflicting with each other, which easily causes the problems such as lack of the main auxiliary patterns around the main pattern, erroneous placement of the main auxiliary patterns, or the like.

Specifically, one main auxiliary pattern is placed between the adjacent feasible edges. Distances t1 and t2 between the main auxiliary pattern and the adjacent feasible edges on two sides are equal, and a width s of the main auxiliary pattern is a second size b.

Since the distances t1 and t2 between the main auxiliary pattern and the adjacent feasible edges on two sides are equal, the spacings between the adjacent feasible edges and the main auxiliary pattern are both equal. The width s of the main auxiliary pattern is the second size b, so that the width s is set as an optimal width when the main auxiliary pattern is designed.

The width s of the main auxiliary pattern has great impact on the light filling effect of the adjacent main patterns. Therefore, for the width s of the main auxiliary pattern and the spacing between the main auxiliary pattern and the adjacent feasible edges, priority is given to ensuring that the width s of the main auxiliary pattern is optimal, that is, the second size b.

In this form, a distance between the main auxiliary pattern and each of the adjacent feasible edges is acquired as a first distance t0. The first distance t0 is acquired as a basis for whether to adjust the main auxiliary pattern subsequently.

In this form, it is determined whether the first distance t0 is greater than or equal to the minimum spacing i between each of the adjacent main patterns and the auxiliary pattern.

Specifically, when the first distance t0 is less than the minimum spacing i between each of the adjacent main patterns and the auxiliary pattern, the width s of the main auxiliary pattern is reduced, and the step of acquiring the distances between the main auxiliary pattern and the adjacent feasible edges is performed.

When the first distance t0 is less than the minimum spacing i between each of the adjacent main patterns and the auxiliary pattern, the first distance t0 does not satisfy the MRC condition. Therefore, the width s of the main auxiliary pattern is reduced from two sides of the main auxiliary pattern to the middle, so that the spacings between the main auxiliary pattern and the adjacent feasible edges on two sides are kept the same all the time. In addition, the first distances t0 from two sides of the main auxiliary pattern can be increased, to cause the first distance t0 to satisfy the MRC condition.

In this form, in the step of reducing the width s of the main auxiliary pattern, the width is decreased by a first preset size each time.

In the step of reducing the width s of the main auxiliary pattern, the width is decreased by a same size each time, so that the width s of the main auxiliary pattern is decreased uniformly and regularly. Algorithms for reducing the width s of the main auxiliary pattern each time are unified. A method for adjusting the width s of the main auxiliary pattern by a loop iteration is simplified. Therefore, the step of adding the auxiliary pattern is prevented from being too tedious and confusing, which facilitates stable implementation of the first distance t0 being greater than or equal to the minimum spacing i between each of the adjacent main patterns and the auxiliary pattern.

It would be appreciated that, a first preset size should be neither excessively large nor excessively small. If the first preset size is excessively large, a step size of the loop iteration is excessively large, and the width s of the main auxiliary pattern is reduced too much each time, which is likely to cause the finally obtained width s of the main auxiliary pattern to be excessively small. As a result, it is likely to cause the insufficient light filling of the main auxiliary pattern to the adjacent main patterns, and cause the finally obtained first distance t0 to be much greater than the minimum spacing i between each of the adjacent main patterns and the auxiliary pattern, resulting in an unnecessary waste of space of the layout layer. If the first preset size is excessively small, the step size of the loop iteration is excessively small, and the width s of the main auxiliary pattern is reduced too little each time. In this way, it is likely to cause an excessively large number of loop iterations and prolong the time of adding the auxiliary pattern, which increases the unnecessary time and operation costs. Therefore, in this form, the first preset size ranges from 0.2 nm to 2 nm. For example, the first preset size is 0.6 nm, 1 nm, or 1.5 nm.

In this form, when the first distance t0 is greater than or equal to the minimum spacing i between each of the adjacent main patterns and the auxiliary pattern, the placing one main auxiliary pattern between the adjacent feasible edges is performed.

When the first distance t0 is greater than or equal to the minimum spacing i between each of the adjacent main patterns and the auxiliary pattern, the first distance t0 satisfies the MRC condition, and the width of the main auxiliary pattern being the second size b also satisfies the MRC condition. Therefore, the placing one main auxiliary pattern between the adjacent feasible edges is performed.

It would be appreciated that, when the first distance t0 is greater than the first size a, although the first distance t0 is already greater than the optimal spacing between the main auxiliary pattern and the main pattern, in order to cause the main auxiliary pattern not to be exposed, the width s of the main auxiliary pattern is less than or equal to the resolution of the lithography process. Therefore, the width s of the main auxiliary pattern should not be excessively large. The width s of the main auxiliary pattern is the second size b, which is already the optimal size and is sufficient to fill the main pattern with light, improve the light intensity contrast, and enhance the lithography process window. Therefore, when the first distance t0 is greater than the first size a, the placing one main auxiliary pattern between the adjacent feasible edges is still performed.

In this form, it is determined whether the spacing d0 between the adjacent feasible edges is less than a second spacing. The second spacing is the sum of twice the first size a, twice the second size b, and the minimum spacing k between the adjacent auxiliary patterns.

The second spacing is a classification basis for whether the two main auxiliary patterns placed between the adjacent feasible edges may be placed at an optimal position.

It would be appreciated that, for the adjacent feasible edges, a condition under which the main auxiliary pattern may be placed at the optimal position on the side portion of one of the feasible edges is that the spacing between the main auxiliary pattern and the feasible edge is greater than or equal to b. A condition under which the main auxiliary pattern may be placed at the optimal position on the side portion of another feasible edge is also that the spacing between the main auxiliary pattern and the feasible edge is greater than or equal to b, and an optimal width allowing placing the main auxiliary patterns is a. In addition, a condition of placing two main auxiliary patterns further includes that the spacing between the two adjacent main auxiliary patterns is k. That is, the minimum spacing allowing placing the two main auxiliary patterns with the optimal width at the optimal position is the sum of twice the first size a, twice the second size b, and the minimum spacing k between the adjacent auxiliary patterns. Therefore, for the adjacent feasible edges, when the spacing d0 between the adjacent feasible edges is greater than or equal to 2a+2b+k, the two main auxiliary patterns with the optimal width can be placed at the optimal position between the adjacent feasible edges. When the spacing d0 between the adjacent feasible edges is less than 2a+2b+k, a position at which the main auxiliary pattern is placed between the adjacent feasible edges or the width s of the main auxiliary pattern needs to be adjusted, that is, the second spacing is 2a+2b+k.

Specifically, when the spacing d0 between the adjacent feasible edges is less than the second spacing, one main auxiliary pattern is placed on each of two sides of a center line of the spacing between the adjacent feasible edges. A spacing between the two main auxiliary patterns is the minimum spacing k between the adjacent auxiliary patterns, distances between the two main auxiliary patterns and the center line are both equal, and the width s of the main auxiliary pattern is the second size b. The width s of the main auxiliary pattern includes a width s1 and a width s2 of the two main auxiliary patterns.

One main auxiliary pattern is placed on each of the two sides of the center line of the spacing between the adjacent feasible edges, and the distances between the two main auxiliary patterns and the center line are both equal, so that the distances t1 and t2 between the main auxiliary pattern and the adjacent feasible edges on two sides are equal. Therefore, the spacings between the adjacent feasible edges and the main auxiliary pattern are both equal. The widths s1 and s2 of the main auxiliary patterns are both the second size b, so that the width s of the main auxiliary pattern is set as an optimal width when the main auxiliary pattern is designed.

The width s of the main auxiliary pattern has great impact on the light filling effect of the adjacent main patterns. Therefore, for the width s of the main auxiliary pattern and the spacing between the main auxiliary pattern and the adjacent feasible edges, priority is given to ensuring that the width s of the main auxiliary pattern is optimal, that is, the second size b.

In this form, the distance between the main auxiliary pattern and the adjacent feasible edge is acquired as a second distance T0. The second distance T0 is acquired as a basis for whether to adjust the main auxiliary pattern subsequently.

In this form, it is determined whether the second distance T0 is greater than or equal to the minimum spacing i between each of the adjacent main patterns and the auxiliary pattern.

Specifically, when the second distance T0 is less than the minimum spacing i between each of the adjacent main patterns and the auxiliary pattern, the widths s1 and s2 and of the two main auxiliary patterns are reduced, and the step of acquiring the distances between the main auxiliary pattern and the adjacent feasible edges is performed.

When the second distance T0 is less than the minimum spacing i between each of the adjacent main patterns and the auxiliary pattern, the second distance T0 does not satisfy the MRC condition. Therefore, the widths s1 and s2 of the two main auxiliary patterns are reduced from two sides of each of the main auxiliary patterns to the middle, so that the spacings between the main auxiliary pattern and the adjacent feasible edges on two sides are kept the same all the time. In addition, the second distances TO from two sides of the main auxiliary pattern can be increased, to cause the second distance T0 to satisfy the MRC condition.

In this form, the widths of the two main auxiliary patterns are each decreased by a second preset size each time.

The widths of the two main auxiliary patterns are each decreased by a same size each time, so that the widths s1 and s2 of the two main auxiliary patterns are decreased uniformly and regularly. Algorithms for reducing the widths s1 and s2 of the two main auxiliary patterns each time are unified. A method for adjusting the width s of the main auxiliary pattern by a loop iteration is simplified. Therefore, the step of adding the auxiliary pattern facilitates stable implementation of the second distance T0 being greater than or equal to the minimum spacing i between each of the adjacent main patterns and the auxiliary pattern.

It would be appreciated that, a second preset size should be neither excessively large nor excessively small. If the second preset size is excessively large, a step size of the loop iteration is excessively large, and the widths s1 and s2 of the two main auxiliary patterns are reduced too much each time, which is likely to cause the finally obtained the widths s1 and s2 of the two main auxiliary patterns to be excessively small. As a result, it is likely to cause the insufficient light filling of the main auxiliary pattern to the adjacent main patterns, and cause the finally obtained second distance T0 to be much greater than the minimum spacing i between each of the adjacent main patterns and the auxiliary pattern, resulting in an unnecessary waste of space of the layout layer. If the second preset size is excessively small, the step size of the loop iteration is excessively small, and the widths s1 and s2 of the two main auxiliary patterns is reduced too little each time. In this way, it is likely to cause an excessively large number of loop iterations and prolong the time of adding the auxiliary pattern, which increases the unnecessary time and operation costs. Therefore, in this form, the second preset size ranges from 0.2 nm to 2 nm. For example, the second preset size is 0.6 nm, 1 nm, or 1.5 nm.

In this form, when the second distance T0 is greater than or equal to the minimum spacing i between each of the adjacent main patterns and the auxiliary pattern, the placing two main auxiliary patterns between the adjacent feasible edges is performed.

When the second distance T0 is greater than or equal to the minimum spacing i between each of the adjacent main patterns and the auxiliary pattern, the second distance T0 satisfies the MRC condition, and the width of the main auxiliary pattern being the second size b also satisfies the MRC condition. Therefore, the placing two main auxiliary patterns between the adjacent feasible edges is performed.

In this form, when the spacing d0 between the adjacent feasible edges is greater than or equal to the second spacing, the main auxiliary pattern adjacent to the corresponding feasible edge is placed at a position at a distance of the first size a from any of the feasible edges. The width s of the main auxiliary pattern is the second size b.

When the spacing d0 between the adjacent feasible edges is greater than or equal to the second spacing, the optimal position between the adjacent feasible edges is sufficient to place the main auxiliary pattern with the optimal width. Therefore, the main auxiliary pattern adjacent to the corresponding feasible edge is placed at a position at a distance of the first size a from any of the feasible edges, and the width s of the main auxiliary pattern is the second size b.

In this form, when no adjacent main pattern is present on the side portion of the feasible edge of the main pattern, one main auxiliary pattern is placed on the side portion of the feasible edge.

In this form, when no adjacent main patterns are present on the side portion of the feasible edge of the main pattern, one main auxiliary pattern may be placed on the side portion of the feasible edge.

In this form, when no adjacent main patterns are present on the side portion of the feasible edge of the main pattern, in the step of placing one main auxiliary pattern to the side portion of the feasible edge, the main auxiliary pattern is placed at a position at a distance of the first size a from the feasible edge, and the width of the main auxiliary pattern is the second size b.

When no adjacent main patterns are present on the side portion of the feasible edge of the main pattern, the optimal position of the side portion of the feasible edge is sufficient to place the main auxiliary pattern with the optimal width. Therefore, the main auxiliary pattern is placed at a position at a distance of the first size a from the feasible edge, and the width of the main auxiliary pattern is the second size b.

In this form, when the spacing d0 between the adjacent feasible edges is greater than or equal to the third spacing, or when no adjacent main patterns are present on the side portion of the feasible edge of the main pattern, in the auxiliary pattern addition module 504, after the main auxiliary patterns are sequentially added to the side portions of the feasible edges of the main pattern, other auxiliary patterns are placed on the side of the main auxiliary pattern away from the feasible edge. The third spacing is the sum of twice the first size a, twice the second size b, twice the minimum spacing k between the adjacent auxiliary patterns, and the minimum width j of the auxiliary pattern, that is, the third spacing equals 2a+2b+2k+j.

It would be appreciated that, the main auxiliary pattern is the auxiliary pattern that has the greatest impact on the main pattern. Therefore, the other auxiliary patterns are placed when it is ensured that the main auxiliary pattern is placed at the optimal position and has the optimal width.

Therefore, for the adjacent feasible edges, a condition under which the main auxiliary pattern may be placed at the optimal position on the side portion of one of the feasible edges is that the spacing between the main auxiliary pattern and the feasible edge is greater than or equal to b. A condition under which the main auxiliary pattern may be placed at the optimal position on the side portion of another feasible edges is also that the spacing between the main auxiliary pattern and the feasible edge is greater than or equal to b, and an optimal width allowing placing the main auxiliary pattern is a. In addition, a condition of placing three auxiliary patterns includes that the spacing between two adjacent auxiliary patterns is k, and a width allowing placing the third auxiliary pattern should be greater than or equal to j. That is, the minimum spacing d0 allowing placing other auxiliary patterns is the sum of twice the first size a, twice the second size b, the minimum spacing k between the adjacent auxiliary patterns, and the minimum width j of the auxiliary pattern. Therefore, for the adjacent feasible edges, when the spacing d0 between the adjacent feasible edges is greater than or equal to 2a+2b+2k+j, the other auxiliary patterns can be placed between the adjacent feasible edges, that is, the third spacing is 2a+2b+2k+j.

When the spacing d0 between the adjacent feasible edges is greater than or equal to the third spacing, or when no adjacent main patterns are present on the side portion of the feasible edge of the main pattern, there is also space allowing placing the other auxiliary patterns after the main auxiliary pattern is placed on the side portion of the feasible edge, so as to further fill light for the main pattern. Therefore, the imaging deviation generated by different main patterns due to different diffraction effects is reduced, the lithography quality of the main pattern is enhanced, and the fidelity of the main pattern is improved.

It would be appreciated that, in this form, after the auxiliary pattern is added to the side portion of the feasible edge of the main pattern, optical proximity correction processing is performed on the main pattern.

In other forms, before the auxiliary pattern is added to the side portion of the feasible edge of the main pattern, the optical proximity correction processing may further be performed on the main pattern. That is, after the optical proximity correction processing is performed on the main pattern, the auxiliary pattern is added to the side portion of the feasible edge of the main pattern.

Correspondingly, the present disclosure further provides a mask. The mask includes patterns obtained by using the optical proximity correction method provided in the forms of the present disclosure.

It may be learned from the foregoing forms that the auxiliary patterns are usually sub-resolution assist features. That is, the auxiliary pattern is an unexposable pattern. By adding the auxiliary pattern around the main pattern, the imaging deviation generated by different main patterns due to different diffraction effects is reduced. Therefore, the fidelity of patterns can be improved, and the lithography quality of the main pattern can be enhanced. In addition, in this form, the forbidden edge rule is set, and the quantity of the auxiliary patterns added to the side portions of the main patterns is obtained based on the forbidden edge rule, so that the auxiliary patterns can be added according to the actual environmental condition around the main pattern. In this way, a result of the optical proximity correction processing is improved.

In some forms, the ascending order of the quantity of the feasible edges of the main pattern is descending order of a quantity of the forbidden edges of the main pattern. More forbidden edges of the main pattern lead to higher likelihood of defects during lithography. That is, higher likelihood of defects of the main pattern leads to higher priority of adding the main auxiliary pattern to the main pattern, and the main auxiliary pattern is the auxiliary pattern closest to the feasible edge, so that the main auxiliary pattern is a pattern that has the greatest impact on the main pattern among the auxiliary patterns. Therefore, in the forms of the present disclosure, the main pattern that easily produces defects is first selected, and the main auxiliary pattern is preferably added to the main pattern that easily produces the defects, so that the proper main auxiliary pattern can be placed on the side portion of the main pattern that easily produces the defects in a targeted manner, to prevent problems such as lack of the main auxiliary patterns around the main pattern that easily produces defects after the auxiliary patterns are added to the entire layout layer or the erroneous addition of the main auxiliary patterns. Therefore, the probability of readjusting the arrangement of the auxiliary patterns after the auxiliary patterns are added to the entire layout layer can be reduced, the time to add the auxiliary patterns can be shortened, and the efficiency of adding the auxiliary patterns can be enhanced. In addition, the probability of defect occurring in the follow-up lithography process can be reduced. Based on the above, it is beneficial to improving the processing result of the optical proximity correction processing.

A form of the present further provides a device. The device may implement the optical proximity correction method provided in the forms of the present disclosure by loading the optical proximity correction method in the form of a program. An hardware structure of a terminal device provided in a form of the present disclosure may be shown in FIG. 10, and includes at least one processor 01, at least one communication interface 02, at least one memory 03, and at least one communication bus 04.

In this form, at least one processor 01, at least one communication interface 02, at least one memory 03, and at least one communication bus 04 are provided. The processor 01, the communication interface 02, and the memory 03 communicate with each other by using the communication bus 04. The communication interface 02 may be an interface of a communication module configured to perform network communication, for example, an interface of a GSM module. The processor 01 may be a central processing unit (CPU), or an application specific integrated circuit (ASIC), or one or more integrated circuits configured to implement the forms of the present disclosure. The memory 03 may include a high-speed random access memory (RAM), or may include a non-volatile memory (NVM), for example, at least one disk memory. The memory 03 stores one or more computer instructions. The one or more computer instructions are executed by the processor 01 to implement the optical proximity correction method provided in the forms of the present disclosure.

It should be noted that the foregoing terminal device for implementation may further include other devices (not shown) that may not be necessary for the disclosure content of the forms of the present disclosure. Since the other devices may not be necessary for understanding the disclosure content of the forms of the present disclosure, the devices are not to be described one by one in the forms of the present disclosure.

A form of the present disclosure further provides a storage medium, storing one or more computer instructions. The one or more computer instructions are used for implementing the optical proximity correction method provided in the forms of the present disclosure.

In the optical proximity correction method provided in the forms of the present disclosure, the auxiliary patterns are usually sub-resolution assist features. That is, the auxiliary pattern is an unexposable pattern. By adding the auxiliary pattern around the main pattern, the imaging deviation generated by different main patterns due to different diffraction effects is reduced. Therefore, the fidelity of patterns can be improved, and the lithography quality of the main pattern can be enhanced. In addition, in this form, the forbidden edge rule is set, and the quantity of the auxiliary patterns added to the side portions of the main patterns is obtained based on the forbidden edge rule, so that the auxiliary patterns can be added according to the actual environmental condition around the main pattern. In this way, a result of the optical proximity correction processing is improved.

In some forms, the ascending order of the quantity of the feasible edges of the main pattern is descending order of a quantity of the forbidden edges of the main pattern. More forbidden edges of the main pattern lead to higher likelihood of defects during lithography. That is, higher likelihood of defects of the main pattern leads to higher priority of adding the main auxiliary pattern to the main pattern, and the main auxiliary pattern is the auxiliary pattern closest to the feasible edge, so that the main auxiliary pattern is a pattern that has the greatest impact on the main pattern among the auxiliary patterns. Therefore, in the forms of the present disclosure, the main pattern that easily produces defects is first selected, and the main auxiliary pattern is preferably added to the main pattern that easily produces the defects, so that the proper main auxiliary pattern can be placed on the side portion of the main pattern that easily produces the defects in a targeted manner, to prevent problems such as lack of the main auxiliary patterns around the main pattern that easily produces defects after the auxiliary patterns are added to the entire layout layer or the erroneous addition of the main auxiliary patterns. Therefore, the probability of readjusting the arrangement of the auxiliary patterns after the auxiliary patterns are added to the entire layout layer can be reduced, the time to add the auxiliary patterns can be shortened, and the efficiency of adding the auxiliary patterns can be enhanced. In addition, the probability of defect occurring in the follow-up lithography process can be reduced. Based on the above, it is beneficial to improving the processing result of the optical proximity correction processing.

The implementations of the present disclosure described above are a combination of elements and features of the present disclosure. The elements or features may be considered selective unless otherwise mentioned. Each element or feature can be practiced without being combined with other elements or features. In addition, the implementations of the present disclosure may be configured by combining a part of elements and/or features. The order of operations described in the implementations of the present disclosure may be rearranged. Some configurations of any implementation may be included in another implementation and may be replaced with corresponding configurations of another implementation.

It is obvious to a person skilled in the art that claims that do not have a clear reference relationship with each other may be combined into an implementation of the present disclosure, or may be included as new claims in amendments after the filing of this application.

The implementations of the present disclosure can be implemented by various means such as hardware, firmware, software, or a combination thereof. In a hardware configuration mode, the method according to the exemplary forms of the present disclosure may be implemented by one or more application specific integrated circuits (ASICs), digital signal processors (DSPs), digital signal processing devices (DSPDs), programmable logic devices (PLD), field programmable gate arrays (FPGAs), processors, controllers, microcontrollers, microprocessors, and the like. In a firmware or software configuration mode, the implementations of the present disclosure may be implemented in the form of modules, processes, functions, and the like. Software code may be stored in a memory unit and executed by a processor. The memory unit is located inside or outside the processor and can send data to and receive data from the processor by various known means.

The foregoing descriptions of the disclosed forms enable a person skilled in the art to implement or use the present disclosure. Various modifications to these forms are obvious to a person skilled in the art, and the general principles defined in this specification may be implemented in other forms without departing from the spirit or scope of the present disclosure. Therefore, the present disclosure is not limited to these forms illustrated herein, but conforms to the broadest scope consistent with the principles and novel features disclosed in the present disclosure.

Although the present disclosure is disclosed as above, the present disclosure is not limited thereto. Any person skilled in the art can make various changes and modifications without departing from the spirit and the scope of the present disclosure, and therefore the protection scope of the present disclosure should be subject to the scope defined by the claims.

What is claimed is:

1. An optical proximity correction method, comprising:
providing main patterns;
setting a forbidden edge rule according to a spacing between adjacent main patterns; and
adding an auxiliary pattern to a side portion of the main patterns, wherein a quantity of auxiliary patterns added to side portions of the main patterns is obtained based on the forbidden edge rule, the forbidden edge rule defining whether an edge of the main patterns is a forbidden edge, where an auxiliary pattern is not added to a side portion of the forbidden edge.

2. The optical proximity correction method according to claim 1, wherein:
providing the main patterns comprises providing a layout layer comprising the main patterns;
setting the forbidden edge rule comprises:
acquiring the spacing between the adjacent main patterns;
for each of the main patterns, in response to a spacing between an edge of the main pattern and an adjacent main pattern being less than a minimum spacing allowing for addition of the auxiliary pattern, selecting an edge of the main pattern as a forbidden edge; and
using remaining edges other than forbidden edges as feasible edges, wherein the minimum spacing allowing for the addition of the auxiliary pattern is a sum of a minimum width of the auxiliary pattern and twice a minimum spacing between each of the main patterns and auxiliary patterns adjacent to the main pattern;
the method further comprises:
acquiring a quantity of the feasible edges of each main pattern; and
the adding the auxiliary pattern to the side portion of the main patterns comprises:
in the layout layer, adding the auxiliary patterns to side portions of the feasible edges of each main pattern, wherein the auxiliary patterns comprise main auxiliary patterns closest to the feasible edges, and sequentially adding the main auxiliary patterns to the side portions of the feasible edges of each main pattern in ascending order of the quantity of the feasible edges of the each main pattern.

3. The optical proximity correction method according to claim 2, wherein sequentially adding the main auxiliary patterns to the side portions of the feasible edges of the each main pattern comprises adding the main auxiliary patterns to the main patterns having a same quantity of feasible edges.

4. The optical proximity correction method according to claim 2, wherein sequentially adding the main auxiliary patterns to the side portions of the feasible edges of the main pattern comprises:
determining whether a side portion of a feasible edge of the main pattern has other adjacent feasible edges;
in response to the feasible edge of the main pattern having an adjacent feasible edge, detecting a spacing between the feasible edge and the adjacent feasible edge;
adding one main auxiliary pattern between the feasible edge and the adjacent feasible edge when the spacing between the feasible edge and the adjacent feasible edge is less than a first spacing, and adding two main auxiliary patterns between the feasible edge and the adjacent feasible edge when the spacing between the feasible edge and the adjacent feasible edge is greater than or equal to the first spacing, wherein the first spacing is a sum of twice a minimum spacing between each of adjacent auxiliary patterns and the main pattern, twice the minimum width of the auxiliary pattern, and the minimum spacing between the adjacent auxiliary patterns; and
in response to no adjacent main patterns being present on the side portion of the feasible edge of the main pattern, adding one main auxiliary pattern on the side portion of the feasible edge.

5. The optical proximity correction method according to claim 4, wherein:
before adding an auxiliary pattern, the method further comprises:
acquiring an optimal spacing between the main auxiliary pattern and the main pattern as a first size based on data of design of experiments (DOE), and acquiring an optimal width of the auxiliary pattern as a second size; and
adding one main auxiliary pattern on the side portion of the feasible edge comprises:
adding the main auxiliary pattern at a position at a distance of the first size from the feasible edge, wherein a width of the main auxiliary pattern is the second size.

6. The optical proximity correction method according to claim 4, wherein in the step of adding the main auxiliary pattern between the feasible edge and the adjacent feasible edge, spacing between feasible edges and the main auxiliary pattern is equal to spacing between the adjacent feasible edge and the main auxiliary pattern.

7. The optical proximity correction method according to claim 4, wherein:
before adding an auxiliary pattern, the method further comprises:
acquiring an optimal spacing between the main auxiliary pattern and the main pattern as a first size based on data of design of experiments (DOE), and acquiring an optimal width of the auxiliary pattern as a second size; and
adding one main auxiliary pattern between the feasible edge and the adjacent feasible edge comprises:
adding one main auxiliary pattern between the feasible edge and the adjacent feasible edge, wherein a distance between the main auxiliary pattern and the feasible edge is equal to a distance between the main auxiliary pattern and the adjacent feasible edge, and a width of the main auxiliary pattern is the second size; and
the method further comprises:
acquiring a distance between the main auxiliary pattern and the adjacent feasible edge as a first distance;
determining whether the first distance is greater than or equal to the minimum spacing between each of the main patterns and auxiliary patterns adjacent to the main pattern;
in response to the first distance being less than the minimum spacing between each of the main patterns and auxiliary patterns adjacent to the main pattern, decreasing the width of the main auxiliary pattern and performing the step of acquiring the distance between the main auxiliary pattern and the adjacent feasible edge; and
in response to the first distance being greater than or equal to the minimum spacing between each of the main patterns and auxiliary patterns adjacent to the main pattern, adding one main auxiliary pattern between the feasible edge and the adjacent feasible edge.

8. The optical proximity correction method according to claim 7, wherein decreasing the width of the main auxiliary pattern comprises incrementally decreasing the width of the main auxiliary pattern by a first preset size.

9. The optical proximity correction method according to claim 8, wherein the first preset size ranges from 0.2 nm to 2 nm.

10. The optical proximity correction method according to claim 4, wherein:
before adding an auxiliary pattern, the method further comprises:
acquiring an optimal spacing between the main auxiliary pattern and the main pattern as a first size based on data of design of experiments (DOE), and acquiring an optimal width of the auxiliary pattern as a second size; and
adding two main auxiliary patterns between the feasible edge and the adjacent feasible edge comprises:
determining whether the spacing between the feasible edge and the adjacent feasible edge is less than a second spacing, wherein the second spacing is a sum of twice the first size, twice the second size, and the minimum spacing between the adjacent auxiliary patterns;
adding one main auxiliary pattern on each of two sides of a center line of the spacing between the feasible edge and the adjacent feasible edge when the spacing between the feasible edge and the adjacent feasible edge is less than the second spacing, wherein a spacing between the two main auxiliary patterns is the minimum spacing between the adjacent auxiliary patterns, distances between the two main auxiliary patterns and the center line are equal, and the width of the main auxiliary pattern is the second size; and
the method further comprises:
acquiring a distance between the main auxiliary pattern and the feasible edge and a distance between the main auxiliary pattern and the adjacent feasible edge as second distances;
determining whether the second distances are greater than or equal to the minimum spacing between each of the main patterns and auxiliary patterns adjacent to the main pattern;
decreasing widths of the two main auxiliary patterns when the second distances are both less than the minimum spacing between each of the main patterns and auxiliary patterns adjacent to the main pattern, and performing the step of acquiring the second distances;
in response to the second distances being greater than or equal to the minimum spacing between each of the main patterns and auxiliary patterns adjacent to the main pattern, performing the step of adding two main auxiliary patterns between the feasible edge and the adjacent feasible edge; and
in response to the spacing between the feasible edge and the adjacent feasible edge being greater than or equal to the second spacing, adding the main auxiliary pattern adjacent to a corresponding feasible edge at a position at a distance of the first size from any of the feasible edges, wherein the width of the main auxiliary pattern is the second size.

11. The optical proximity correction method according to claim 10, wherein decreasing the widths of the two main auxiliary patterns comprises incrementally decreasing the widths of the two main auxiliary patterns by a second preset size.

12. The optical proximity correction method according to claim 11, wherein the second preset size ranges from 0.2 nm to 2 nm.

13. The optical proximity correction method according to claim 4, wherein:
before adding an auxiliary pattern, the method further comprises:
acquiring an optimal spacing between the main auxiliary pattern and the main pattern as a first size based on data of design of experiments (DOE), and acquiring an optimal width of the auxiliary pattern as a second size; and
when the spacing between the feasible edge and the adjacent feasible edge is greater than or equal to a third spacing, or when no adjacent main patterns are present on side portions of the feasible edges of the main pattern, the adding the auxiliary patterns to the side portions of the feasible edges of the main pattern further comprises:
after sequentially adding the main auxiliary patterns to the side portions of the feasible edges of the main pattern, adding other auxiliary patterns on a side of the main auxiliary patterns away from the feasible edges, wherein the third spacing is a sum of twice the first size, twice the second size, twice the minimum spacing between the adjacent auxiliary patterns, and the minimum width of the auxiliary pattern.

14. The optical proximity correction method according to claim 2, wherein in the step of adding the auxiliary patterns to the side portions of the feasible edges of the main pattern, the auxiliary patterns comprise a scattering bar (SBar).

15. An optical proximity correction system, comprising:
a memory operable to store computer-readable instructions; and
processor circuitry operable to read the computer-readable instructions stored in the memory, the processor circuitry when executing the computer-readable instructions is configured to:
provide main patterns;
set a forbidden edge rule according to a spacing between adjacent main patterns; and
add an auxiliary pattern to a side portion of the main patterns, wherein a quantity of the auxiliary patterns added to side portions of the main patterns is obtained based on the forbidden edge rule, the forbidden edge rule defining whether an edge of the main patterns is a forbidden edge, where an auxiliary pattern is not added to a side portion of the forbidden edge.

16. The optical proximity correction system according to claim 15, wherein the processor circuitry is further configured to:
provide a layout layer comprising the main patterns;
for each of the main patterns, in response to a spacing between an edge of the main pattern and an adjacent main pattern being less than a minimum spacing allowing for addition of the auxiliary pattern, select the edge of the main pattern as a forbidden edge;
use remaining edges other than forbidden edges as feasible edges, wherein the minimum spacing allowing for the addition of the auxiliary pattern is a sum of a minimum width of the auxiliary pattern and twice a minimum spacing between each of the main patterns and auxiliary patterns adjacent to the main pattern;
acquire a quantity of the feasible edges of each main pattern; and
in the layout layer, add the auxiliary patterns to side portions of the feasible edges of the each main pattern, wherein the auxiliary patterns comprise main auxiliary patterns closest to the feasible edges, and sequentially add the main auxiliary patterns to the side portions of the feasible edges of the each main pattern in ascending order of the quantity of the feasible edges of the each main pattern.

17. A mask, comprising patterns obtained using the optical proximity correction method according to claim 1.

18. A non-transitory machine-readable media, having instructions stored on the machine readable media, the instructions configured to, when executed, cause a machine to:
provide main patterns;
set a forbidden edge rule according to a spacing between adjacent main patterns; and
add an auxiliary pattern to a side portion of the main patterns, wherein a quantity of the auxiliary patterns added to side portions of the main patterns is obtained based on the forbidden edge rule, the forbidden edge rule defining whether an edge of the main patterns is a forbidden edge, where an auxiliary pattern is not added to a side portion of the forbidden edge.
